(19) United States
(12) Patent Application Publication
(10) Pub. No.: US 2026/0225941 A1
(43) Pub. Date: Aug. 6, 2026

(54) GLASS

(71) Applicant: AGC Inc., Tokyo (JP)

(72) Inventors: Rikiya KADO, Tokyo (JP); Hirofumi TOKUNAGA, Tokyo (JP); Mamoru ISOBE, Tokyo (JP); Yuha KOBAYASHI, Tokyo (JP)

(73) Assignee: AGC Inc., Tokyo (JP)

(21) Appl. No.: 19/636,706

(22) Filed: Apr. 1, 2026

Related U.S. Application Data
(63) Continuation of application No. PCT/JP2024/036287, filed on Oct. 10, 2024.

(30) Foreign Application Priority Data
Oct. 13, 2023 (JP) 2023-177361

(51) Int. Cl. C03C 3/091

(52) U.S. Cl. CPC C03C 3/091

(57) ABSTRACT

To facilitate manufacturing while minimizing deflection. Provided is a glass 10 in which a parameter A is 0.817 or less, a parameter B is 0.898 or more, a ratio of a content of MgO to a total content of a divalent oxide RO is 0.65 or more in terms of mol % on an oxide basis, a Young's modulus is 80 GPa or more, and the glass is an alkali-free glass.

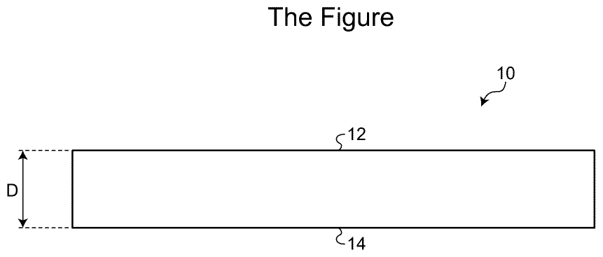

### CROSS-REFERENCE TO RELATED APPLICATIONS

This application is a continuation of International Application No. PCT/JP2024/036287, filed on Oct. 10, 2024 which claims the benefit of priority of the prior Japanese Patent Application No. 2023-177361, filed on Oct. 13, 2023, the entire contents of which are incorporated herein by reference.

### BACKGROUND OF THE INVENTION

### 1. Field of the Invention

The present invention relates to a glass.

### 2. Description of the Related Art

Glass may be used as a member for supporting a semiconductor device during the manufacturing process of the semiconductor device. For example, JP 2021-20840 A describes a supporting glass substrate having a high Young's modulus in order to minimize deflection.

Glass having a high Young's modulus in order to minimize the deflection as described above often exhibits a viscosity curve unsuitable for manufacturing, that is, temperature dependency of viscosity depending on a component added to have a high Young's modulus, and is required to be easily manufactured.

### SUMMARY OF THE INVENTION

It is an object of the present invention to at least partially solve the problems in the conventional technology.

The glass of the present disclosure has a parameter A represented by Equation (1) 0.817 or less, has a parameter B represented by Equation (2) 0.898 or more, has a ratio of a content of MgO to a total content of a divalent metal oxide RO 0.65 or more in terms of mol % on an oxide basis, has a Young's modulus 80 GPa or more, and is an alkali-free glass.

$$A == 1.747 - 0.022 \times [ {SiO}_{2} ] + 0.006 \times [ {Al}_{2} {O}_{3} ] + 0.018 \times [ {B}_{2} {O}_{3} ] + 0.013 \times [ MgO ] - 0.01 \times [ CaO ] - 0.003 \times [ SrO ] + 0.012 \times [ BaO ] + 0.015 \times [ ZnO ] \qquad ( 1 )$$

$$B = 1.315 - 0.01 \times [ {SiO}_{2} ] + 0.005 \times [ {Al}_{2} {O}_{3} ] + 0.023 \times [ {B}_{2} {O}_{3} ] + 0.004 \times [ MgO ] - 0.016 \times [ CaO ] - 0.007 \times [ SrO ] + 0.011 \times [ BaO ] + 0.01 \times [ ZnO ] \qquad ( 2 )$$

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWING

The FIGURE is a schematic diagram of a glass according to the present embodiment.

### DETAILED DESCRIPTION OF THE PREFERRED EMBODIMENTS

Hereinafter, suitable embodiments of the present invention will be described in detail with reference to the accompanying drawings. The present invention is not limited to the embodiments, and in a case where a plurality of embodiments is provided, the present invention includes a combination of the embodiments. The numerical value includes a range of rounding. The numerical range represented by “to” means a numerical range including numerical values before and after “to” as a lower limit value and an upper limit value, and in a case where “to” is used in the following description, the same meaning is given. The upper limit and the lower limit indicated in the numerical range can be appropriately combined.

### Glass

The FIGURE is a schematic diagram of a glass according to the present embodiment. As illustrated in the FIGURE, a glass 10 according to the present embodiment is used as a glass substrate for manufacturing a semiconductor package, and more specifically, is a supporting glass substrate for manufacturing FOWLP or the like. However, the use of the glass 10 is not limited to the manufacturing FOWLP or the like, and may be optional, and the glass 10 may be a glass substrate used for supporting a member or may be used for purposes other than supporting the member. FOWLP or the like include a fan out wafer level package (FOWLP) and a fan out panel level package (FOPLP).

### Composition of Glass

Next, a preferable composition of the glass 10 will be described.

### Parameter A

A parameter A of the glass 10 is represented by the following Equation (1).

$$A = 1.747 - 0.022 \times [ {SiO}_{2} ] + 0.006 \times [ {Al}_{2} {O}_{3} ] + 0.018 \times [ {B}_{2} {O}_{3} ] + 0.013 \times [ MgO ] - 0.01 \times [ CaO ] - 0.003 \times [ SrO ] + 0.012 \times [ BaO ] + 0.015 \times [ ZnO ] \qquad ( 1 )$$

The content of the oxide AₓO_{y} (A is an element constituting an oxide, and x and y are any integers) contained in the glass 10 is represented by [AₓO_{y}] in terms of mol % on an oxide basis. The content herein refers to the ratio of the content of the oxide AₓO_{y} to the total glass 10 in terms of mol % on an oxide basis. That is, for example, [SiO₂] in Equation (1) refers to the ratio of the content of SiO₂ to the total glass 10 in terms of mol % on an oxide basis.

In addition, the glass 10 may not contain all the oxides represented by Equation (1). In Equation (1), the content of the oxides not contained in the glass 10 is considered to be zero. In addition, the glass 10 may contain components other than the oxides represented by Equation (1).

The parameter A of the glass 10 is preferably 0.817 or less, more preferably 0.813 or less, more preferably 0.809 or less, more preferably 0.802 or less, more preferably 0.796 or less, and more preferably 0.789 or less. In addition, the parameter A is preferably 0.781 or more, preferably 0.781 or more and 0.817 or less, and is also preferably 0.783 or less, preferably 0.776 or less, and preferably 0.770 or less. When the parameter A is within this range, an increase in the temperature difference between the melting temperature of the glass 10 and the molding temperature is minimized. As a result, an increase in the energy loss at the time of transition from a melting process to a molding process can be minimized, and the production can be facilitated. When the parameter A is within this range, minimizing the excessive decrease in the temperature difference between the molding temperature and the softening temperature can facilitate viscosity control during the molding and can facilitate the manufacturing.

### Parameter B

A parameter B of the glass 10 is represented by the following Equation (2).

$$B = 1.315 - 0.01 \times [ {SiO}_{2} ] + 0.005 \times [ {Al}_{2} {O}_{3} ] + 0.023 \times [ {B}_{2} {O}_{3} ] + 0.004 \times [ MgO ] - 0.016 \times [ CaO ] - 0.007 \times [ SrO ] + 0.011 \times [ BaO ] + 0.01 \times [ ZnO ] \qquad ( 2 )$$

The glass 10 may not contain all the oxides represented by Equation (2). In Equation (2), the content of the oxides not contained in the glass 10 is considered to be zero. In addition, the glass 10 may contain components other than the oxides represented by Equation (2).

The parameter B of the glass 10 is preferably 0.898 or more, more preferably 0.901 or more, more preferably 0.904 or more, more preferably 0.907 or more, more preferably 0.911 or more, more preferably 0.915 or more, more preferably 0.921 or more, more preferably 0.926 or more, and still more preferably 0.931 or more. In addition, the parameter B of the glass 10 is preferably 0.935 or less, and also preferably 0.903 or more and 0.935 or less. When the parameter B is within this range, minimizing the excessive decrease in the temperature difference between the molding temperature and the softening temperature can facilitate viscosity control during the molding, and can facilitate manufacturing.

### SiO₂

The glass 10 preferably contains SiO₂ (the content of SiO₂ is higher than 0 mol %). In order to appropriately minimize an increase in the melting temperature and the liquid phase temperature, the content of SiO₂ in the glass 10 is preferably 55.0% or more and 65.0% or less, more preferably 55% or more and 65% or less, more preferably 57% or more and 64.5% or less, more preferably 59% or more and 64% or less, more preferably 61% or more and 63.5% or less, and still more preferably 61.5% or more and 62.5% or less in terms of mol % on an oxide basis. When the content of SiO₂ is within this range, it is possible to facilitate the manufacturing while minimizing deflection.

Al₂O₃

Al₂O₃ has an effect of increasing Young's modulus to minimize deflection and phase separation of glass. Therefore, it is preferable that the glass 10 contains Al₂O₃. In the glass 10, the content of Al₂O₃ is preferably 3% or more and 13.0% or less, more preferably 5% or more and 11% or less, more preferably 7% or more and 9% or less, more preferably 7.0% or more and 8.5% or less, more preferably 7.2% or more and 8.5% or less, more preferably 7.4% or more and 8% or less, and still more preferably 7.5% or more and 7.7% or less in terms of mol % on an oxide basis. When the content of Al₂O₃ is within this range, it is possible to facilitate the manufacturing while minimizing deflection.

B₂O₃

B₂O₃ has effects of reducing devitrification caused by crystallization of glass to facilitate the manufacturing, and controlling Young's modulus. Therefore, it is preferable that the glass 10 contains B₂O₃. In the glass 10, the content of B₂O₃ is preferably 1.0% or more and 10.0% or less, more preferably 2% or more and 9% or less, more preferably 3% or more and 8.5% or less, more preferably 4% or more and 8% or less, more preferably 5.5% or more and 7.5% or less, more preferably 5.8% or more and 6.8% or less, and still more preferably 6% or more and 6.5% or less in terms of mol % on an oxide basis. When the content of B₂O₃ is within this range, it is possible to facilitate the manufacturing while minimizing deflection.

### MgO/RO

Since MgO increases the Young's modulus without increasing the density, it has an effect of increasing the specific elastic modulus among Group 2 elements, and the ratio of the MgO content to the RO content (MgO/RO) is important for controlling the specific elastic modulus. Therefore, the ratio (MgO/RO) of the glass 10 is preferably 0.65 or more, more preferably 0.65 or more and 0.9 or less, more preferably 0.68 or more and 0.9 or less, more preferably 0.7 or more and 0.85 or less, more preferably 0.72 or more and 0.8 or less, and still more preferably 0.74 or more and 0.77 or less. Here, R refers to a divalent metal, RO refers to an oxide of the divalent metal R, and the content of RO refers to the total content of the divalent oxide. The total content of the divalent oxide refers to the total content of the divalent oxide when a plurality of kinds of divalent oxides are contained, and refers to the content of the divalent oxide when one kind of divalent oxide is contained. When the ratio (MgO/RO) is within this range, it is possible to facilitate the manufacturing while minimizing deflection.

### RO

In the glass 10, the total content of the divalent oxide RO is preferably 10.0% or more and 40.0% or less, more preferably 15% or more and 35% or less, more preferably 17.5% or more and 30% or less, more preferably 20% or more and 27.5% or less, more preferably 22% or more and 26% or less, more preferably 23.5% or more and 25% or less, and still more preferably 24% or more and 24.5% or less in terms of mol % on an oxide basis. When the total content of RO is within this range, it is possible to facilitate the manufacturing while minimizing deflection.

### MgO

Since MgO is a component capable of increasing the Young's modulus without increasing the density, that is, increasing the specific elastic modulus, it is preferable that the glass 10 contains MgO. Among the components increasing the Young's modulus, MgO is a component particularly effective for adjusting the viscosity of glass. For example, although a rare earth oxide is a component that increases the Young's modulus, this component reduces temperature dependency of viscosity at a high temperature range, resulting in an increase in the temperature difference between the melting temperature and the molding temperature. Similarly, although Al₂O₃ is a component that increases Young's modulus to minimize deflection, this component has a high effect of increasing the viscosity of glass, and may impair melt properties and moldability. MgO is a component that also contributes to the viscosity of glass, and is also a component excellent in both manufacturability and minimization of deflection when the content thereof is adjusted. In the glass 10, the content of MgO is preferably 10.0% or more and 25.0% or less, more preferably 12% or more and 22% or less, more preferably 14% or more and 22% or less, more preferably 16% or more and 22% or less, more preferably 16.5% or more and 22% or less, more preferably 16.5% or more and 20% or less, more preferably 16.6% or more and 18.6% or less, more preferably 16.7% or more and 18% or less, and still more preferably 17% or more and 17.7% or less in terms of mol % on an oxide basis. When the content of MgO is within this range, it is possible to facilitate the manufacturing while minimizing deflection.

### Cao

Among the oxides belonging to Group 2 elements, Cao has the second highest effect after MgO in increasing the specific elastic modulus. Therefore, the glass 10 may not contain Cao (the content of Cao is 0 mol %), but may contain CaO. In the glass 10, the content of Cao is preferably 1.0% or more and 10.0% or less, more preferably 1.1% or more and 7% or less, more preferably 1.5% or more and 4.2% or less, more preferably 1.8% or more and 3.7% or less, more preferably 2.2% or more and 3.4% or less, more preferably 2.4% or more and 3% or less, and still more preferably 2.5% or more and 2.7% or less in terms of mol % on an oxide basis. When the content of Cao is within this range, it is possible to facilitate the manufacturing while minimizing deflection.

### Sro

Sro has an effect of increasing the density and controlling the Young's modulus, and improves meltability. The glass 10 may not contain Sro, but may contain Sro. In the glass 10, the content of Sro is preferably 0.1% or more and 5.0% or less, more preferably 0.1% or more and 3.4% or less, more preferably 0.5% or more and 3% or less, more preferably 0.9% or more and 2.6% or less, and still more preferably 1% or more and 2% or less in terms of mol % on an oxide basis. When the content of Sro is within this range, it is possible to facilitate the manufacturing while minimizing deflection.

### Bao

BaO has a greater effect of increasing the density than Sro, and improves the meltability. The glass 10 may not contain Bao, but may contain BaO. In the glass 10, the content of BaO is preferably 0.1% or more and 5.0% or less, more preferably 1% or more and 4.8% or less, more preferably 1.5% or more and 4.7% or less, more preferably 2% or more and 4.5% or less, more preferably 2.5% or more and 4.3% or less, more preferably 3% or more and 4.1% or less, and still more preferably 3.3% or more and 3.8% or less in terms of mol % on an oxide basis. When the content of BaO is within this range, it is possible to facilitate the manufacturing while minimizing deflection.

### ZnO

ZnO has an effect of improving the meltability of glass and increasing the Young's modulus. Therefore, the glass 10 may not contain ZnO, but may contain ZnO. By setting the content of ZnO to 10% or less, an increase in the linear thermal expansion coefficient can be minimized. In the glass 10, the content of ZnO is preferably 0.1% or more and 10% or less, more preferably 0.5% or more and 8% or less, more preferably 1% or more and 7% or less, more preferably 1.5% or more and 6% or less, more preferably 2% or more and 5% or less, more preferably 2.5% or more and 4% or less, and still more preferably 3% or more and 3.5% or less in terms of mol % on an oxide basis. When the content of ZnO is within this range, it is possible to facilitate the manufacturing while minimizing deflection.

### Alkali Metal Oxide

The glass 10 is preferably an alkali-free glass. The alkali-free glass does not substantially contain an alkali metal oxide such as Li₂O, Na₂O, or K₂O. Here, the phrase “does not substantially contain an alkali metal oxide” means that the glass does not contain an alkali metal oxide other than inevitable impurities mixed from a raw material and the like. That is, it means that an alkali metal oxide is not intentionally contained.

For example, in the glass 10, the content of Li₂O is preferably 0%, the content of Na₂O is preferably 0%, and the content of K₂O is preferably 0% in terms of mol % on an oxide basis.

In addition to the above-described components, oxides (sub-oxides) other than the oxides listed above may be contained in order to adjust various mechanical properties, melting properties, and moldability. The oxide described above refers to SiO₂, Al₂O₃, B₂O₃, RO (divalent oxide), and alkali metal oxides. Examples of the sub-oxides include metal oxides such as TiO₂ and ZrO₂, and rare earth oxides such as Y₂O₃ and La₂O₃. The glass 10 may contain the sub-oxides in a total amount of 5% or less, preferably contains 3% or less, more preferably 2% or less, more preferably 1% or less, more preferably 0.5% or less, preferably 0.3% or less, preferably 0.2% or less, and still preferably 0.1% or less in terms of mol % on an oxide basis, and it is particularly preferable that the sub-oxides are substantially not contained.

### PbO

PbO is an oxide having a high environmental load although having an effect of increasing the Young's modulus. Therefore, it is preferable that the glass 10 does not contain PbO. In the glass 10, the content of PbO is preferably 0.1% or less, more preferably 0.05% or less, and still more preferably 0.01% or less in terms of mol % on an oxide basis. When the content of PbO is within this range, the environmental load can be reduced.

Fe₂O₃

The glass 10 preferably does not contain Fe₂O₃. In the glass 10, the content of Fe₂O₃ on an outer percentage basis is preferably 0.1% or less, more preferably 0.001% or more and 0.05% or less, and still more preferably 0.005% or more and 0.01% or less in terms of mass % on an oxide basis. When the content of Fe₂O₃ is as low as described above, a reduction in light transmittance can be minimized.

The content of Fe₂O₃ on an outer percentage basis refers to the ratio of the mass of Fe₂O₃ contained in the glass 10 to the total value of the mass of all the components of the glass 10 excluding Fe₂O₃ in terms of an oxide basis.

### Preferable Composition of Glass

Next, a preferable composition of the glass 10 will be described.

In order to improve the clarity of the glass, the glass 10 can contain, in terms of mass % on an oxide basis, a total amount of SnO₂, CeO₂, Sb₂O₃, SO₃, F, and Cl of 1.0 wt % or less, preferably 0.5 wt % or less, more preferably 0.3 wt % or less, and still more preferably 0.1 wt % or less on an outer percentage basis.

In the glass 10, the ratio of the content of RO to the total content of SiO₂, Al₂O₃, and B₂O₃ ((RO)/(SiO₂+Al₂O₃+B₂O₃)) is preferably 0.2 or more and 0.5 or less, more preferably 0.22 or more and 0.48 or less, more preferably 0.27 or more and 0.44 or less, more preferably 0.29 or more and 0.38 or less, more preferably 0.31 or more and 0.34 or less, and still more preferably 0.32 or more and 0.33 or less in terms of mol % on an oxide basis. When the ratio ((RO)/(SiO₂+Al₂O₃+B₂O₃)) is within this range, both Young's modulus and meltability can be achieved.

In the glass 10, the total amount (SiO₂+Al₂O₃+MgO+CaO) of SiO₂, Al₂O₃, MgO, and CaO is preferably 85% or more and 98% or less, more preferably 86% or more and 95% or less, more preferably 87% or more and 93% or less, and still more preferably 88% or more and 91% or less in terms of mol % on an oxide basis. When the lower limit of the total amount (SiO₂+Al₂O₃+MgO+CaO) is as high as described above, the density and the Young's modulus can be controlled, and when the upper limit is within this range, the deterioration of meltability can be minimized.

In the glass 10, the difference (Al₂O₃—RO) that is a value obtained by subtracting the content of RO from the content of Al₂O₃ is preferably −30% or more and 0% or less, more preferably −28.5% or more and −5% or less, more preferably −25% or more and −8% or less, more preferably-22% or more and −12% or less, more preferably −20% or more and −14% or less, and still more preferably −18% or more and −16% or less in terms of mol % on an oxide basis. When (Al₂O₃—RO) is within this range, both Young's modulus and meltability can be achieved.

It is preferable that the glass 10 contains, in terms of mol % on an oxide basis,
SiO₂: 60.5% to 61.5%,
Al₂O₃: 7.2% to 7.7%,
B₂O₃: 6.0% to 7.0%,
MgO: 17.0% to 18.0%,
CaO: 3.5% to 4.5%,
SrO: 0.0% to 1.0%, and
BaO: 2.5% to 3.5%.

When the content of each oxide is within this range, it is possible to facilitate the manufacturing while minimizing deflection.

When the composition of the glass 10 is within the range described above, it is preferable that the glass 10 does not contain oxides other than those listed above except for inevitable impurities.

The glass 10 preferably does not contain a sintered body. That is, the glass 10 is preferably glass that is not a sintered body. Here, the sintered body refers to a member in which a plurality of particles are heated at a temperature lower than the melting point to bond the particles to one another. The porosity of the sintered body is high to some extent because the sintered body includes vacancies, but the porosity of the glass 10 is low because the glass 10 is not a sintered body, and the porosity is thus usually 0%. However, it is allowable to include an inevitable trace amount of pores. The porosity herein is a so-called true porosity, and refers to a value obtained by dividing a sum of volumes of pores (vacancy) communicating with the outside and pores (vacancy) not communicating with the outside by a total volume (apparent volume). The porosity can be measured according to, for example, JIS R 1634:1998 “Measuring Methods for Sintered Body Density and Open Porosity of Fine Ceramics”.

In addition, it is preferable that glass used for the glass 10 is usually amorphous glass, that is, amorphous solid. In addition, although this glass may be crystallized glass containing crystals on the surface or inside, amorphous glass is preferable from the viewpoint of density. Among the ceramics, those produced by a sintering method are preferably not used because of a low transmittance and a high density.

### Shape of Glass

Next, the shape of the glass 10 will be described. As illustrated in the FIGURE, the glass 10 is a plate-like glass substrate including a surface 12 serving as a principal surface on one side and a surface 14 serving as a principal surface opposite to the surface 12. The surface 14 may be, for example, parallel to the surface 12. Although the glass 10 may have a circular disk shape in plan view, that is, when viewed from a direction orthogonal to the surface 12, the shape is not limited to the circular disk shape, may be any shape, and may be a polygonal plate such as a rectangle. The shape also includes a shape in which cutouts such as a notch or an orientation flat are provided on the outer periphery.

A thickness D of the glass 10, that is, the length between the surface 12 and the surface 14 is preferably 0.1 mm or more and 5.0 mm or less, more preferably 0.1 mm or more and 2.0 mm or less, and still more preferably 0.1 mm or more and 0.7 mm or more. By setting the thickness D to 0.1 mm or more, it is possible to prevent the glass 10 from being too thin and to minimize breakage due to deflection or impact. By setting the thickness D to 2.0 mm or less, it is possible to minimize an increase in weight, and by setting the thickness D to 0.7 mm or less, it is possible to further minimize an increase in weight suitably.

### Properties of Glass

Next, the properties of the glass 10 will be described.

### Young's Modulus

A Young's modulus E of the glass 10 is preferably 75 GPa or more, more preferably 77 GPa or more and 120 GPa or less, more preferably 79 GPa or more and 100 GPa or less, more preferably 81 GPa or more and 90 GPa or less, more preferably 83 GPa or more and 87 GPa or less, and still more preferably 84 GPa or more and 86 GPa or less. By setting the Young's modulus E within this range, deflection can be appropriately minimized. When the Young's modulus is too high, cutting, grinding, and polishing processing are difficult.

### Young's Modulus Parameter

A Young's modulus parameter Y of the glass 10 calculated from the composition is preferably 0.9 or more, more preferably 0.95 or more and 1.15 or less, more preferably 0.96 or more and 1.10 or less, more preferably 0.97 or more and 1.05 or less, more preferably 0.98 or more and 1.04 or less, more preferably 0.99 or more and 1.03 or less, and still more preferably 1.00 or more and 1.02 or less. When the Young's modulus parameter Y is set within this range, the Young's modulus E can be set within the above-described range, and the deflection can be appropriately minimized.

The Young's modulus parameter Y is calculated from the following Equation (3).

$$Y = ( 60 - 0.244 [ {SiO}_{2} ] + 0.27 [ {Al}_{2} {O}_{3} ] - 0.6 [ {B}_{2} {O}_{3} ] + 0.63 [ MgO ] + 0.48 [ CaO ] - 0.56 [ SrO ] - 0.22 [ BaO ] + 1.37 [ ZnO ] ) / 85 \qquad ( 3 )$$

### Density

A density ρ of the glass 10 is preferably 2.4 g/cm³ or more and 2.9 g/cm³ or less, more preferably 2.45 g/cm³ or more and 2.85 g/cm³ or less, more preferably 2.5 g/cm³ or more and 2.8 g/cm³ or less, more preferably 2.55 g/cm³ or more and 2.75 g/cm³ or less, more preferably 2.57 g/cm³ or more and 2.7 g/cm³ or less, more preferably 2.59 g/cm³ or more and 2.65 g/cm³ or less, and still more preferably 2.6 g/cm³ or more and 2.63 g/cm³ or less.

### E/ρ

A ratio (E/ρ) of the Young's modulus E to the density p of the glass 10 is preferably 30 GPa·cm³/g or more and 40 GPa·cm³/g or less, more preferably 30.5 GPa·cm³/g or more and 38 GPa·cm³/g or less, more preferably 31 GPa·cm³/g or more and 36 GPa·cm³/g or less, more preferably 31.5 GPa·cm³/g or more and 34 GPa·cm³/g or less, more preferably 32 GPa·cm³/g or more and 33.5 GPa·cm³/g or less, more preferably 32.2 GPa·cm³/g or more and 33 GPa·cm³/g or less, and still more preferably 32.4 GPa·cm³/g or more and 32.7 GPa·cm³/g or less. Since by setting the lower limit of the ratio (E/p) to be within this range, the deflection can be minimized while the weight is reduced, handling is facilitated even in the processing. When the upper limit of the ratio (E/p) is within this range, the occurrence of cracks during the processing can be minimized.

### Linear Thermal Expansion Coefficient

A linear thermal expansion coefficient α of the glass 10 is preferably 5.8 ppm/° C. or lower, more preferably 3.6 ppm/° C. or higher and 5.6 ppm/° C. or lower, more preferably 3.8 ppm/° C. or higher and 5.2 ppm/° C. or lower, more preferably 4 ppm/° C. or higher and 5.2 ppm/° C. or lower, more preferably 4.2 ppm/° C. or higher and 4.8 ppm/° C. or lower, more preferably 4.3 ppm/° C. or higher and 4.6 ppm/° C. or lower, and more preferably 4.35 ppm/° C. or higher and 4.5 ppm/° C. or lower.

By setting the linear thermal expansion coefficient within this range, deflection can be appropriately minimized. The linear thermal expansion coefficient α is an average thermal expansion coefficient within a range of 20° C. to 300° C., and is a value measured in accordance with DIN-51045-1 as a standard for thermal expansion measurement. For example, the measurement may be performed within a range of 0° C. to 350° C. using a thermal expansion meter, DIL 402 Expedis Supreme, manufactured by NETZSCH Group as a measuring apparatus, and an average thermal expansion coefficient within a range of 20° C. to 300° C. in that measurement range may be used as the linear thermal expansion coefficient.

Melting Temperature T₂, Working Temperature T₃, Molding Temperature T₄, Softening Temperature T_{7.65}

A melting temperature T₂ of the glass 10 is preferably 1400° C. or higher and 1650° C. or lower, more preferably 1410° C. or higher and 1620° C. or lower, more preferably 1440° C. or higher and 1590° C. or lower, more preferably 1470° C. or higher and 1560° C. or lower, more preferably 1480° C. or higher and 1550° C. or lower, more preferably 1490° C. or higher and 1540° C. or lower, more preferably 1500° C. or higher and 1530° C. or lower, and more preferably 1510° C. or higher and 1520° C. or lower. The melting temperature T₂ refers to a temperature at which a viscosity η is 102 dPa·s. When the melting temperature T₂ is relatively low as described above, melting can be facilitated. In addition, since the melting temperature T₂ is relatively high, it can be made equal to the melting temperature of other general commercial glasses. As a result, it facilitates the adjustment of melting equipment required for a change in the base composition.

A working temperature T₃ of the glass 10 is preferably 1200° C. or higher and 1400° C. or lower, more preferably 1215° C. or higher and 1390° C. or lower, more preferably 1240° C. or higher and 1380° C. or lower, more preferably 1260° C. or higher and 1370° C. or lower, more preferably 1290° C. or higher and 1360° C. or lower, more preferably 1315° C. or higher and 1350° C. or lower, and still more preferably 1325° C. or higher and 1345° C. or lower. The working temperature T₃ refers to a temperature at which a viscosity η is 10³ dPa·s. When the working temperature T₃ is relatively low as described above, molding can be facilitated.

A molding temperature T₄ of the glass 10 is preferably 1080° C. or higher and 1300° C. or lower, more preferably 1100° C. or higher and 1280° C. or lower, more preferably 1120° C. or higher and 1260° C. or lower, more preferably 1140° C. or higher and 1240° C. or lower, more preferably 1160° C. or higher and 1220° C. or lower, more preferably 1180° C. or higher and 1215° C. or lower, more preferably 1190° C. or higher and 1210° C. or lower, and more preferably 1200° C. or higher and 1205° C. or lower. The molding temperature T₄ refers to a temperature at which a viscosity η is 10⁴ dPa·s. When the molding temperature T₄ is relatively low as described above, molding can be facilitated.

A softening temperature T_{7.65} of the glass 10 is preferably 800° C. or higher and 1000° C. or lower, more preferably 830° C. or higher and 980° C. or lower, more preferably 850° C. or higher and 960° C. or lower, more preferably 870° C. or higher and 940° C. or lower, more preferably 890° C. or higher and 925° C. or lower, more preferably 900° C. or higher and 920° C. or lower, and more preferably 905° C. or higher and 915° C. or lower. The softening temperature T_{7.65} refers to a temperature at which the viscosity η is 107.65 dPa·s. When the softening temperature T_{7.65} is relatively low as described above, molding can be facilitated.

The melting temperature T₂, the working temperature T₃, and the molding temperature T₄ can be measured by an inner cylinder rotation method or the like. The softening temperature T_{7.65} (° C.) can be measured by a method defined according to JIS R 3103-1 “Viscosity and viscometric fixed points of glass-Part 1: Determination of softening point”.

T₂-T₄

The glass 10 preferably has a difference (T₂-T₄) between the melting temperature T₂ and the molding temperature T₄ of 280° C. or higher and 340° C. or lower. The difference (T₂-T₄) may be 400° C. or lower, 290° C. or higher and 375° C. or lower, 295° C. or higher and 360° C. or lower, 298° C. or higher and 340° C. or lower, 300° C. or higher and 320° C. or lower, 305° C. or higher and 315° C. or lower, or 307° C. or higher and 310° C. or lower. Since the difference (T₂-T₄) is relatively small as described above, the temperature gradient from the melting process to the molding process decreases. As a result, an increase in energy loss at the time of process transition can be minimized, and manufacturing can be facilitated. When the difference (T₂-T₄) is too small, the change range of the viscosity with respect to the temperature is too large, and it is difficult to control the melting and molding temperature from the melting process to the molding process.

T₄-T_{7.65}

In the glass 10, the difference (T₄-T_{7.65}) between the molding temperature T₄ and the softening temperature T_{7.65} is preferably 290° C. or higher, and more preferably 290° C. or higher and 300° C. or lower. The difference (T₄-T_{7.65}) may be 250° C. or higher, 250° C. or higher and 350° C. or lower, 260° C. or higher and 335° C. or lower, 270° C. or higher and 315° C. or lower, 280° C. or higher and 305° C. or lower, 285° C. or higher and 300° C. or lower, or 290° C. or higher and 295° C. or lower. When the difference (T₄-T_{7.65}) is small, precise temperature control is required when the viscosity of glass is controlled in the molding process. It is difficult to perform precise temperature control in large-scale manufacturing equipment, and not only there is a possibility that it cannot be molded into a designed shape, but also cracks and breakages may occur. Since the difference (T₄-T_{7.65}) is relatively large as described above, viscosity control during the molding is facilitated, and manufacturing can be facilitated.

### Method for Manufacturing Glass

The glass 10 may be manufactured by any method, and is manufactured, for example, by the following method. First, a raw material such as silica sand or soda ash, which is a raw material of the compound contained in the glass 10, is heated at a predetermined temperature (for example, 1500° C. to 1600° C.) to be melted. Then, after the melted raw material (glass) is clarified, a molding process of molding the raw material into a plate shape is executed. The molded glass is a glass that falls within the composition range of the glass 10 described above on an oxide basis. Then, a slow cooling process is performed on the glass molded in the molding process to manufacture the glass 10.

The method for manufacturing the glass 10 is not limited to the above, and any methods may be adopted. For example, the slow cooling process is not necessary. In addition, various methods can be adopted as the molding process in manufacturing the glass 10, and examples thereof include a melt casting method, a down draw method (for example, an overflow down draw method, a slot down method, a redrawing method, and the like), a float method, a roll-out method, and a press method.

Next, an example of a manufacturing process in a case where the glass 10 is used for manufacturing FOWLP will be described. In the manufacturing FOWLP, a plurality of semiconductor chips are bonded to the glass 10, and the semiconductor chips are covered with an encapsulating material to form an element substrate. Then, the glass 10 and the element substrate are separated, and a surface of the element substrate opposite to a surface of the element substrate on which the semiconductor chips are disposed is bonded to, for example, another glass 10. Then, wiring, solder bumps, and the like are formed on the semiconductor chips, and the element substrate and the glass 10 are separated again. The element substrate is then cut into pieces for each semiconductor chip to obtain a semiconductor device.

### Effects

As described above, in the glass 10 according to a first aspect of the present disclosure, the parameter A is 0.817 or less, the parameter B is 0.898 or more, the ratio (MgO/RO) of the content of MgO to the total content of the divalent oxide RO is 0.65 or more in terms of mol % on an oxide basis, the Young's modulus E is 80 GPa or more, and the glass is an alkali-free glass.

Since the glass 10 of the present disclosure is an alkali-free glass having Young's modulus E of 80 GPa or more, deflection can be appropriately minimized. However, in the alkali-free glass having a high Young's modulus, in general, the difference (T₂-T₄) between the melting temperature T₂ and the molding temperature T₄ tends to increase, and the difference (T₄-T_{7.65}) between the molding temperature T₄ and the softening temperature T_{7.65} tends to decrease. When the difference (T₂-T₄) is large, the temperature is greatly lowered at the time of transition from the melting process to the molding process, and the energy loss increases. In addition, when the difference (T₄-T_{7.65}) is small, an allowable temperature range in the molding process is small, and it is thus difficult to control the viscosity, resulting in difficulty of molding.

On the other hand, as a result of intensive studies, the present inventors have found that by setting the parameters A and B and the ratio (MgO/RO) within these ranges described above, it is possible to appropriately control the difference (T₂-T₄) becoming excessively large and the difference (T₄-T_{7.65}) becoming excessively small. That is, in the glass 10 of the present disclosure, since the parameters A, B and the ratio (MgO/RO) are within these ranges described above, it is possible to reduce the difficulty for controlling the viscosity while minimizing the increase in the energy loss in the transition from the melting process to the molding process. Therefore, according to the present disclosure, it is possible to provide the glass 10 that is easily manufacturable while deflection is minimized.

In the alkali-free glass having a Young's modulus E of 80 GPa or more, the specific elastic modulus E/p (Young's modulus/density) tends to increase, and there is a possibility that cracks are easily generated during the processing. In addition, for example, when the specific elastic modulus E/p is too small, it is easy to crack and is too heavy, resulting in difficulty to handle in the processing. On the other hand, since the parameters A, B and the ratio (MgO/RO) of the glass 10 of the present disclosure are within these ranges described above, the specific elastic modulus E/p can be maintained in an appropriate range, and the glass can be easily handled in the processing while reducing cracks during the processing.

A glass 10 according to a second aspect of the present disclosure is the glass 10 according to the first aspect, in which the glass 10 preferably contains, in terms of mol % on an oxide basis,
SiO₂: 55.0% to 65.0%,
Al₂O₃: 3.0% to 13.0%,
B₂O₃: 1.0% to 10.0%, and
RO: 10.0% to 40.0%.

According to the present disclosure, it is possible to facilitate the manufacturing while minimizing deflection.

A glass 10 according to a third aspect of the present disclosure is the glass 10 according to the first aspect or the second aspect, in which the glass 10 preferably contains, in terms of mol % on an oxide basis,

### MgO: 10.0% to 25.0%.

According to the present disclosure, it is possible to facilitate the manufacturing while minimizing deflection.

A glass 10 according to a fourth aspect of the present disclosure is the glass 10 according to any one of the first to third aspects, in which the glass 10 preferably contains, in terms of mol % on an oxide basis,

### CaO: 1.0% to 10.0%.

According to the present disclosure, it is possible to facilitate the manufacturing while minimizing deflection.

A glass 10 according to a fifth aspect of the present disclosure is the glass 10 according to any one of the first to fourth aspects, in which the glass 10 preferably contains, in terms of mol % on an oxide basis,

### SrO: 0% to 5.0%.

According to the present disclosure, it is possible to facilitate the manufacturing while minimizing deflection.

A glass 10 according to a sixth aspect of the present disclosure is the glass 10 according to any one of the first to fifth aspects, in which the glass 10 preferably contains, in terms of mol % on an oxide basis,

### BaO: 0% to 5.0%.

According to the present disclosure, it is possible to facilitate the manufacturing while minimizing deflection.

A glass 10 according to a seventh aspect of the present disclosure is the glass 10 according to any one of the first aspect to the sixth aspect, in which it is preferable to use the glass 10 as a substrate. The glass 10 of the present disclosure is suitably used for a substrate.

A glass 10 according to an eighth aspect of the present disclosure is the glass 10 according to the seventh aspect, in which it is preferable that the glass is used for manufacturing at least one of a fan out wafer level package or a fan out panel level package. The glass 10 is suitably used for these applications.

### EXAMPLES

Next, examples will be described. Tables 1-1 to 1-3 are tables showing the properties of the glass of each example. The embodiments may be modified as long as the effects of the invention are obtained.

TABLE 1-1

| | Exam- | Exam- | Exam- | Exam- | Exam- | Exam- | Exam- | Exam- | Exam- | Exam- |
|---|---|---|---|---|---|---|---|---|---|---|
| (mol %) | ple 1 | ple 2 | ple 3 | ple 4 | ple 5 | ple 6 | ple 7 | ple 8 | ple 9 | ple 10 |
| SiO₂ | 61.0 | 61.0 | 61.0 | 61.5 | 61.5 | 61.5 | 61.5 | 61.5 | 61.5 | 61.5 |
| Al₂O₃ | 7.5 | 8.0 | 8.0 | 7.5 | 7.5 | 7.5 | 8.0 | 8.0 | 8.0 | 8.5 |
| B₂O₃ | 6.5 | 6.5 | 7.0 | 6.0 | 6.5 | 6.5 | 6.0 | 6.5 | 6.5 | 6.0 |
| MgO | 17.5 | 17.0 | 16.5 | 17.5 | 17.0 | 17.5 | 17.0 | 16.5 | 17.0 | 16.5 |
| CaO | 4.0 | 3.5 | 3.0 | 3.5 | 2.5 | 2.5 | 3.5 | 2.0 | 2.0 | 3.5 |
| SrO | 0.5 | 1.5 | 2.0 | | 1.5 | 2.0 | 0.5 | 2.5 | 2.0 | 0.5 |
| BaO | 3.0 | 2.5 | 2.5 | 4.0 | 3.5 | 2.5 | 3.5 | 3.0 | 3.0 | 3.5 |
| ZnO | | | | | | | | | | |
| ZrO₂ | | | | | | | | | | |
| TiO₂ | | | | | | | | | | |
| Y₂O₃ | | | | | | | | | | |
| La₂O₃ | | | | | | | | | | |
| SnO₂ | | | | | | | | | | |
| CeO₂ | | | | | | | | | | |
| Sb₂O₃ | | | | | | | | | | |
| MgO/RO | 0.70 | 0.69 | 0.69 | 0.70 | 0.69 | 0.71 | 0.69 | 0.69 | 0.71 | 0.69 |
| RO/(SiO₂ + Al₂O₃ + B₂O₃) | 0.33 | 0.32 | 0.32 | 0.33 | 0.32 | 0.32 | 0.32 | 0.32 | 0.32 | 0.32 |
| SiO₂ + Al₂O₃ + MgO + CaO | 90.0 | 89.5 | 88.5 | 90.0 | 88.5 | 89.0 | 90.0 | 88.0 | 88.5 | 90.0 |
| Al₂O₃ − RO | −17.5 | −16.5 | −16.0 | −17.5 | −17.0 | −17.0 | −16.5 | −16.0 | −16.0 | −15.5 |
| A | 0.799 | 0.791 | 0.797 | 0.798 | 0.799 | 0.792 | 0.787 | 0.792 | 0.800 | 0.783 |
| B | 0.907 | 0.903 | 0.918 | 0.913 | 0.922 | 0.910 | 0.904 | 0.919 | 0.924 | 0.905 |
| Y | 1.00 | 0.99 | 0.97 | 1.00 | 0.98 | 0.98 | 0.99 | 0.97 | 0.97 | 0.99 |
| ρ(g/cm³) | 2.60 | 2.60 | 2.60 | 2.62 | 2.62 | 2.60 | 2.61 | 2.62 | 2.61 | 2.61 |
| E(GPa) | 85 | 84 | 84 | 85 | 84 | 84 | 85 | 83 | 84 | 85 |
| E/ρ(GPa · cm³/g) | 32.7 | 32.5 | 32.2 | 32.5 | 32.0 | 32.3 | 32.6 | 31.9 | 32.1 | 32.6 |
| α(ppm/° C., 20° C.-300° C.) | 4.37 | 4.32 | 4.31 | 4.42 | 4.41 | 4.32 | 4.36 | 4.37 | 4.31 | 4.31 |
| T₂(° C.) | 1506 | 1513 | 1514 | 1512 | 1514 | 1511 | 1518 | 1517 | 1517 | 1529 |
| T₃(° C.) | 1334 | 1332 | 1335 | 1337 | 1336 | 1336 | 1338 | 1333 | 1335 | 1341 |
| T₄(° C.) | 1203 | 1197 | 1200 | 1204 | 1203 | 1203 | 1203 | 1196 | 1200 | 1203 |
| T_{7.65}(° C.) | 910 | 903 | 904 | 911 | 908 | 909 | 909 | 902 | 907 | 908 |
| T₄ − T_{7.65}(° C.) | 293 | 293 | 296 | 293 | 295 | 294 | 294 | 294 | 293 | 295 |
| T₂ − T₄(° C.) | 303 | 316 | 314 | 308 | 312 | 308 | 315 | 321 | 316 | 326 |
| Manufacturability | ∘ | ∘ | ∘ | ∘ | ∘ | ∘ | ∘ | ∘ | ∘ | ∘ |
| Deflection | ∘ | ∘ | ∘ | ∘ | ∘ | ∘ | ∘ | ∘ | ∘ | ∘ |
| | Exam- | Exam- | Exam- | Exam- | Exam- | Exam- | Exam- | Exam- | Exam- | Exam- |
| (mol %) | ple 11 | ple 12 | ple 13 | ple 14 | ple 15 | ple 16 | ple 17 | ple 18 | ple 19 | ple 20 |
| SiO₂ | 61.5 | 62.0 | 62.0 | 62.0 | 62.0 | 62.0 | 62.0 | 62.0 | 62.0 | 62.0 |
| Al₂O₃ | 8.5 | 7.0 | 7.0 | 7.5 | 7.5 | 7.5 | 7.5 | 8.0 | 8.0 | 8.0 |
| B₂O₃ | 6.5 | 6.0 | 6.0 | 6.0 | 6.0 | 6.0 | 6.0 | 6.0 | 6.0 | 6.5 |
| MgO | 16.0 | 17.5 | 18.0 | 17.0 | 17.0 | 17.5 | 18.0 | 16.5 | 17.0 | 16.0 |
| CaO | 3.0 | 3.5 | 3.0 | 3.0 | 3.5 | 2.5 | 2.0 | 3.5 | 3.0 | 3.5 |
| SrO | 0.5 | | | 1.0 | | 1.0 | 1.0 | | | |
| BaO | 4.0 | 4.0 | 4.0 | 3.5 | 4.0 | 3.5 | 3.5 | 4.0 | 4.0 | 4.0 |
| ZnO | | | | | | | | | | |
| ZrO₂ | | | | | | | | | | |
| TiO₂ | | | | | | | | | | |
| Y₂O₃ | | | | | | | | | | |
| La₂O₃ | | | | | | | | | | |
| SnO₂ | | | | | | | | | | |
| CeO₂ | | | | | | | | | | |
| Sb₂O₃ | | | | | | | | | | |
| MgO/RO | 0.68 | 0.70 | 0.72 | 0.69 | 0.69 | 0.71 | 0.73 | 0.69 | 0.71 | 0.68 |
| RO/(SiO₂ + Al₂O₃ + B₂O₃) | 0.31 | 0.33 | 0.33 | 0.32 | 0.32 | 0.32 | 0.32 | 0.32 | 0.32 | 0.31 |
| SiO₂ + Al₂O₃ + MgO + CaO | 89.0 | 90.0 | 90.0 | 89.5 | 90.0 | 89.5 | 89.5 | 90.0 | 90.0 | 89.5 |
| Al₂O₃ − RO | −15.0 | −18.0 | −18.0 | −17.0 | −17.0 | −17.0 | −17.0 | −16.0 | −16.0 | −15.5 |
| A | 0.797 | 0.784 | 0.795 | 0.776 | 0.781 | 0.788 | 0.799 | 0.777 | 0.789 | 0.780 |
| B | 0.928 | 0.905 | 0.915 | 0.901 | 0.906 | 0.911 | 0.921 | 0.906 | 0.916 | 0.916 |
| Y | 0.98 | 1.00 | 1.00 | 0.99 | 1.00 | 0.99 | 0.99 | 0.99 | 0.99 | 0.99 |
| ρ(g/cm³) | 2.62 | 2.62 | 2.62 | 2.62 | 2.62 | 2.61 | 2.61 | 2.62 | 2.61 | 2.61 |
| E(GPa) | 85 | 85 | 85 | 84 | 85 | 85 | 85 | 85 | 85 | 84 |
| E/ρ(GPa · cm³/g) | 32.3 | 32.4 | 32.5 | 32.3 | 32.5 | 32.4 | 32.5 | 32.5 | 32.6 | 32.3 |
| α(ppm/° C., 20° C.-300° C.) | 4.32 | 4.44 | 4.40 | 4.39 | 4.39 | 4.36 | 4.32 | 4.35 | 4.31 | 4.32 |
| T₂(° C.) | 1526 | 1519 | 1519 | 1522 | 1522 | 1516 | 1521 | 1534 | 1532 | 1535 |
| T₃(° C.) | 1336 | 1340 | 1343 | 1340 | 1341 | 1340 | 1342 | 1343 | 1345 | 1343 |
| T₄(° C.) | 1197 | 1206 | 1210 | 1204 | 1206 | 1207 | 1209 | 1203 | 1206 | 1203 |
| T_{7.65}(° C.) | 902 | 912 | 916 | 908 | 910 | 914 | 915 | 907 | 910 | 904 |
| T₄ − T_{7.65}(° C.) | 296 | 295 | 294 | 295 | 295 | 293 | 293 | 296 | 297 | 299 |
| T₂ − T₄(° C.) | 329 | 312 | 308 | 318 | 316 | 308 | 312 | 331 | 326 | 333 |
| Manufacturability | ∘ | ∘ | ∘ | ∘ | ∘ | ∘ | ∘ | ∘ | ∘ | ∘ |
| Deflection | ∘ | ∘ | ∘ | ∘ | ∘ | ∘ | ∘ | ∘ | ∘ | ∘ |

TABLE 1-2

| | Exam- | Exam- | Exam- | Exam- | Exam- | Exam- | Exam- | Exam- | Exam- | Exam- |
|---|---|---|---|---|---|---|---|---|---|---|
| (mol %) | ple 21 | ple 22 | ple 23 | ple 24 | ple 25 | ple 26 | ple 27 | ple 28 | ple 29 | ple 30 |
| SiO₂ | 62.0 | 62.0 | 62.5 | 62.5 | 62.5 | 62.5 | 62.5 | 62.5 | 62.5 | 62.5 |
| Al₂O₃ | 8.0 | 8.5 | 7.0 | 7.0 | 7.5 | 7.5 | 7.5 | 7.5 | 8.0 | 8.0 |
| B₂O₃ | 6.5 | 6.0 | 6.0 | 6.0 | 5.5 | 6.0 | 6.0 | 6.0 | 5.5 | 6.0 |
| MgO | 16.5 | 16.0 | 17.5 | 18.0 | 18.0 | 16.5 | 17.0 | 17.5 | 17.0 | 16.0 |
| CaO | 2.0 | 3.0 | 2.5 | 2.5 | 2.5 | 3.0 | 2.0 | 2.0 | 2.5 | 2.0 |
| SrO | 1.0 | 0.5 | 1.0 | 0.5 | | 0.5 | 1.0 | 0.5 | 0.5 | 2.0 |
| BaO | 4.0 | 4.0 | 3.5 | 3.5 | 4.0 | 4.0 | 4.0 | 4.0 | 4.0 | 3.5 |
| ZnO | | | | | | | | | | |
| ZrO₂ | | | | | | | | | | |
| TiO₂ | | | | | | | | | | |
| Y₂O₃ | | | | | | | | | | |
| La₂O₃ | | | | | | | | | | |
| SnO₂ | | | | | | | | | | |
| CeO₂ | | | | | | | | | | |
| Sb₂O₃ | | | | | | | | | | |
| MgO/RO | 0.70 | 0.68 | 0.71 | 0.73 | 0.73 | 0.69 | 0.71 | 0.73 | 0.71 | 0.68 |
| RO/(SiO₂ + Al₂O₃ + B₂O₃) | 0.31 | 0.31 | 0.32 | 0.32 | 0.32 | 0.32 | 0.32 | 0.32 | 0.32 | 0.31 |
| SiO₂ + Al₂O₃ + MgO + CaO | 88.5 | 89.5 | 89.5 | 90.0 | 90.5 | 89.5 | 89.0 | 89.5 | 90.0 | 88.5 |
| Al₂O₃ − RO | −15.5 | −15.0 | −17.5 | −17.5 | −17.0 | −16.5 | −16.5 | −16.5 | −16.0 | −15.5 |
| A | 0.798 | 0.777 | 0.774 | 0.782 | 0.784 | 0.766 | 0.781 | 0.789 | 0.772 | 0.762 |
| B | 0.935 | 0.912 | 0.903 | 0.909 | 0.908 | 0.903 | 0.917 | 0.923 | 0.904 | 0.904 |
| Y | 0.98 | 0.99 | 0.99 | 1.00 | 1.00 | 0.99 | 0.98 | 0.99 | 0.99 | 0.97 |
| ρ(g/cm³) | 2.62 | 2.62 | 2.61 | 2.60 | 2.61 | 2.62 | 2.62 | 2.61 | 2.62 | 2.62 |
| E(GPa) | 84 | 85 | 84 | 85 | 86 | 84 | 84 | 85 | 85 | 84 |
| E/ρ(GPa · cm³/g) | 32.1 | 32.4 | 32.3 | 32.5 | 32.8 | 32.2 | 32.1 | 32.4 | 32.5 | 31.9 |
| α(ppm/° C., 20° C.-300° C.) | 4.32 | 4.32 | 4.38 | 4.32 | 4.32 | 4.38 | 4.36 | 4.31 | 4.33 | 4.35 |
| T₂(° C.) | 1532 | 1535 | 1521 | 1524 | 1528 | 1527 | 1528 | 1529 | 1534 | 1532 |
| T₃(° C.) | 1343 | 1344 | 1343 | 1346 | 1348 | 1344 | 1344 | 1346 | 1345 | 1341 |
| T₄(° C.) | 1204 | 1204 | 1209 | 1212 | 1213 | 1207 | 1207 | 1210 | 1207 | 1202 |
| T_{7.65}(° C.) | 906 | 907 | 915 | 917 | 920 | 911 | 911 | 915 | 913 | 907 |
| T₄ − T_{7.65}(° C.) | 298 | 297 | 294 | 295 | 294 | 297 | 296 | 295 | 294 | 295 |
| T₂ − T₄(° C.) | 328 | 331 | 312 | 312 | 315 | 320 | 321 | 319 | 327 | 330 |
| Manufacturability | ∘ | ∘ | ∘ | ∘ | ∘ | ∘ | ∘ | ∘ | ∘ | ∘ |
| Deflection | ∘ | ∘ | ∘ | ∘ | ∘ | ∘ | ∘ | ∘ | ∘ | ∘ |
| | Exam- | Exam- | Exam- | Exam- | Exam- | Exam- | Exam- | Exam- | Exam- | Exam- |
| (mol %) | ple 31 | ple 32 | ple 33 | ple 34 | ple 35 | ple 36 | ple 37 | ple 38 | ple 39 | ple 40 |
| SiO₂ | 62.5 | 63.0 | 63.0 | 63.0 | 63.0 | 63.0 | 63.0 | 63.0 | 63.0 | 61.4 |
| Al₂O₃ | 8.0 | 7.0 | 7.0 | 7.0 | 7.0 | 7.0 | 7.5 | 7.5 | 7.5 | 8.5 |
| B₂O₃ | 6.0 | 5.5 | 5.5 | 6.0 | 6.0 | 6.0 | 5.5 | 6.0 | 6.0 | 6.1 |
| MgO | 16.5 | 18.0 | 18.5 | 16.5 | 17.0 | 18.0 | 17.5 | 16.0 | 17.0 | 17.0 |
| CaO | 1.5 | 2.5 | 1.5 | 3.0 | 3.0 | 1.0 | 1.5 | 3.0 | 1.5 | 3.9 |
| SrO | 2.0 | | | | | 1.0 | 1.5 | | 0.5 | 0.0 |
| BaO | 3.5 | 4.0 | 4.5 | 4.5 | 4.0 | 4.0 | 3.5 | 4.5 | 4.5 | 3.0 |
| ZnO | | | | | | | | | | |
| ZrO₂ | | | | | | | | | | |
| TiO₂ | | | | | | | | | | |
| Y₂O₃ | | | | | | | | | | |
| La₂O₃ | | | | | | | | | | |
| SnO₂ | | | | | | | | | | |
| CeO₂ | | | | | | | | | | |
| Sb₂O₃ | | | | | | | | | | |
| MgO/RO | 0.70 | 0.73 | 0.76 | 0.69 | 0.71 | 0.75 | 0.73 | 0.68 | 0.72 | 0.71 |
| RO/(SiO₂ + Al₂O₃ + B₂O₃) | 0.31 | 0.32 | 0.32 | 0.32 | 0.32 | 0.32 | 0.32 | 0.31 | 0.31 | 0.31 |
| SiO₂ + Al₂O₃ + MgO + CaO | 88.5 | 90.5 | 90.0 | 89.5 | 90.0 | 89.0 | 89.5 | 89.5 | 89.0 | 90.8 |
| Al₂O₃ − RO | −15.5 | −17.5 | −17.5 | −17.0 | −17.0 | −17.0 | −16.5 | −16.0 | −16.0 | −15.4 |
| A | 0.773 | 0.769 | 0.792 | 0.760 | 0.761 | 0.790 | 0.765 | 0.757 | 0.783 | 0.786 |
| B | 0.914 | 0.901 | 0.924 | 0.905 | 0.901 | 0.929 | 0.901 | 0.905 | 0.929 | 0.902 |
| Y | 0.97 | 1.00 | 1.00 | 0.99 | 0.99 | 0.98 | 0.99 | 0.99 | 0.98 | 1.00 |
| ρ(g/cm³) | 2.62 | 2.61 | 2.62 | 2.62 | 2.60 | 2.61 | 2.62 | 2.62 | 2.62 | 2.58 |
| E(GPa) | 84 | 85 | 85 | 84 | 84 | 84 | 84 | 84 | 84 | 84 |
| E/ρ(GPa · cm³/g) | 32.0 | 32.6 | 32.5 | 32.1 | 32.4 | 32.2 | 32.3 | 32.1 | 32.1 | 32.6 |
| α(ppm/° C., 20° C.-300° C.) | 4.32 | 4.34 | 4.34 | 4.42 | 4.35 | 4.31 | 4.31 | 4.37 | 4.32 | 4.34 |
| T₂(° C.) | 1531 | 1530 | 1528 | 1533 | 1532 | 1530 | 1530 | 1541 | 1539 | 1528 |
| T₃(° C.) | 1340 | 1349 | 1349 | 1347 | 1348 | 1348 | 1345 | 1350 | 1350 | 1339 |
| T₄(° C.) | 1201 | 1214 | 1214 | 1209 | 1212 | 1212 | 1209 | 1209 | 1211 | 1200 |
| T_{7.65}(° C.) | 907 | 920 | 921 | 911 | 913 | 916 | 916 | 909 | 913 | 906 |
| T₄ − T_{7.65}(° C.) | 295 | 294 | 293 | 299 | 298 | 296 | 293 | 300 | 298 | 294 |
| T₂ − T₄(° C.) | 330 | 316 | 314 | 324 | 321 | 318 | 321 | 332 | 328 | 327 |
| Manufacturability | ∘ | ∘ | ∘ | ∘ | ∘ | ∘ | ∘ | ∘ | ∘ | ∘ |
| Deflection | ∘ | ∘ | ∘ | ∘ | ∘ | ∘ | ∘ | ∘ | ∘ | ∘ |

TABLE 1-3

| | Exam- | Exam- | Exam- | Exam- | Exam- | Exam- | Exam- | Exam- | Exam- | Exam- |
|---|---|---|---|---|---|---|---|---|---|---|
| (mol %) | ple 41 | ple 42 | ple 43 | ple 44 | ple 45 | ple 46 | ple 47 | ple 48 | ple 49 | ple 50 |
| SiO₂ | 61.4 | 56 | 53 | 63 | 55 | 65 | 61 | 61 | 59 | 57 |
| Al₂O₃ | 8.5 | 5 | 5 | 5 | 5 | 8 | 10 | 10 | 4 | 11 |
| B₂O₃ | 6.1 | 5 | 9 | 6 | 6 | 6 | 8 | 2 | 7 | 3 |
| MgO | 17.0 | 18 | 17 | 12 | 18 | 16 | 11 | 11 | 15 | 20 |
| CaO | 1.0 | 16 | 12 | 14 | 16 | 2 | 7 | 6 | 10 | 1 |
| SrO | 3.0 | | 1 | | | | | 1 | | |
| BaO | 3.0 | | | | | 1 | 3 | 2 | | |
| ZnO | | | 1 | | | 2 | | 8 | 3 | |
| ZrO₂ | | | | | | | | | | |
| TiO₂ | | | 1 | | | | | | 2 | 6 |
| Y₂O₃ | | | | | | | | | | 1 |
| La₂O₃ | | | | | | | | | | |
| SnO₂ | | | | | | | | | | |
| CeO₂ | | | | | | | | | | |
| Sb₂O₃ | | | | | | 1 | | | | |
| MgO/RO | 0.71 | 0.52 | 0.54 | 0.46 | 0.52 | 0.75 | 0.54 | 0.38 | 0.54 | 0.95 |
| RO/(SiO₂ + Al₂O₃ + B₂O₃) | 0.32 | 0.51 | 0.47 | 0.35 | 0.51 | 0.27 | 0.26 | 0.38 | 0.40 | 0.30 |
| SiO₂ + Al₂O₃ + MgO + CaO | 87.9 | 95.1 | 88.1 | 94.1 | 93.4 | 90.4 | 89.1 | 87.4 | 87.5 | 88.7 |
| Al₂O₃ − RO | −15.5 | −28.5 | −26.2 | −20.9 | −28.2 | −13.4 | −10.6 | −17.9 | −23.6 | −10.3 |
| A | 0.805 | 0.662 | 0.891 | 0.513 | 0.717 | 0.710 | 0.745 | 0.728 | 0.769 | 0.859 |
| B | 0.927 | 0.706 | 0.922 | 0.686 | 0.755 | 0.879 | 0.898 | 0.820 | 0.838 | 0.899 |
| Y | 0.97 | 1.07 | 1.03 | 1.03 | 1.05 | 1.03 | 0.96 | 1.13 | 1.04 | 1.03 |
| ρ(g/cm³) | 2.63 | 2.60 | 2.65 | 2.55 | 2.62 | 2.59 | 2.59 | 2.83 | 2.61 | 2.65 |
| E(GPa) | 85 | 89 | 88 | 87 | 90 | 91 | 87 | 95 | 90 | 95 |
| E/ρ(GPa · cm³/g) | 32.1 | 34.3 | 33.1 | 34.7 | 36.6 | 35.0 | 33.4 | 33.5 | 34.5 | 36.0 |
| α(ppm/° C., 20° C.-300° C.) | 4.54 | 5.50 | 5.24 | 4.82 | 5.48 | 3.88 | 4.21 | 4.39 | 4.70 | 4.02 |
| T₂(° C.) | 1513 | 1428 | 1411 | 1529 | 1433 | 1596 | 1533 | 1500 | 1449 | 1464 |
| T₃(° C.) | 1333 | 1252 | 1215 | 1325 | 1243 | 1373 | 1330 | 1307 | 1256 | 1301 |
| T₄(° C.) | 1200 | 1126 | 1083 | 1180 | 1111 | 1218 | 1184 | 1171 | 1120 | 1179 |
| T_{7.65}(° C.) | 909 | 865 | 831 | 886 | 852 | 909 | 886 | 898 | 849 | 913 |
| T₄ − T_{7.65}(° C.) | 290 | 261 | 251 | 294 | 260 | 309 | 298 | 273 | 271 | 266 |
| T₂ − T₄(° C.) | 313 | 303 | 329 | 349 | 321 | 378 | 349 | 328 | 329 | 285 |
| Manufacturability | ∘ | x | x | x | x | x | x | x | x | x |
| Deflection | ∘ | ∘ | ∘ | ∘ | ∘ | ∘ | ∘ | ∘ | ∘ | ∘ |
| | Exam- | Exam- | Exam- | Exam- | Exam- | Exam- | Exam- | Exam- | Exam- | Exam- |
| (mol %) | ple 51 | ple 52 | ple 53 | ple 54 | ple 55 | ple 56 | ple 57 | ple 58 | ple 59 | ple 60 |
| SiO₂ | 58 | 61 | 60 | 58 | 60 | 64 | 59 | 58 | 60 | 64 |
| Al₂O₃ | 11 | 13 | 10 | 9 | 9 | 11 | 10 | 7 | 10 | 13 |
| B₂O₃ | 4 | 5 | 4 | 2 | 2 | 7 | 6 | 4 | 4 | 2 |
| MgO | 23 | 20 | 10 | 17 | 13 | 12 | 16 | 17 | 13 | 18 |
| CaO | 2 | 2 | 7 | 4 | 8 | 7 | 2 | 6 | 10 | 1 |
| SrO | | | | | 4 | | 3 | | | |
| BaO | 1 | | 3 | | 4 | | 1 | | 2 | |
| ZnO | | | 5 | 4 | | | 1 | 5 | | 3 |
| ZrO₂ | | 1 | | | | | 1 | 2 | | |
| TiO₂ | | | | 6 | | | 1 | 1 | | |
| Y₂O₃ | | | | | | | | | | |
| La₂O₃ | | | | | | | | | | |
| SnO₂ | | | | | | | | | | |
| CeO₂ | | | | | | | | | 1 | |
| Sb₂O₃ | | | | | | | | | | |
| MgO/RO | 0.89 | 0.93 | 0.40 | 0.68 | 0.45 | 0.63 | 0.68 | 0.62 | 0.52 | 0.81 |
| RO/(SiO₂ + Al₂O₃ + B₂O₃) | 0.35 | 0.27 | 0.35 | 0.37 | 0.41 | 0.22 | 0.31 | 0.40 | 0.34 | 0.28 |
| SiO₂ + Al₂O₃ + MgO + CaO | 95.0 | 94.6 | 87.1 | 88.2 | 90.0 | 93.5 | 87.0 | 88.4 | 92.5 | 95.1 |
| Al₂O₃ − RO | −14.5 | −8.2 | −15.5 | −16.3 | −20.0 | −7.1 | −13.9 | −20.2 | −15.1 | −9.5 |
| A | 0.906 | 0.824 | 0.742 | 0.810 | 0.651 | 0.614 | 0.831 | 0.821 | 0.682 | 0.734 |
| B | 0.930 | 0.910 | 0.848 | 0.849 | 0.727 | 0.800 | 0.927 | 0.858 | 0.770 | 0.846 |
| Y | 1.06 | 1.04 | 1.07 | 1.10 | 0.99 | 1.00 | 0.98 | 1.10 | 1.02 | 1.10 |
| ρ(g/cm³) | 2.59 | 2.56 | 2.80 | 2.68 | 2.80 | 2.46 | 2.60 | 2.74 | 2.65 | 2.61 |
| E(GPa) | 96 | 96 | 92 | 94 | 88 | 89 | 79 | 97 | 91 | 95 |
| E/ρ(GPa · cm³/g) | 37.3 | 37.4 | 32.9 | 35.2 | 31.5 | 36.3 | 30.2 | 35.4 | 34.3 | 36.5 |
| α(ppm/° C., 20° C.-300° C.) | 4.05 | 3.68 | 4.53 | 4.11 | 5.35 | 3.73 | 4.36 | 4.47 | 4.67 | 3.52 |
| T₂(° C.) | 1473 | 1517 | 1505 | 1479 | 1489 | 1607 | 1493 | 1467 | 1501 | 1571 |
| T₃(° C.) | 1311 | 1328 | 1308 | 1301 | 1299 | 1382 | 1319 | 1297 | 1310 | 1358 |
| T₄(° C.) | 1189 | 1194 | 1169 | 1173 | 1165 | 1225 | 1188 | 1171 | 1174 | 1214 |
| T_{7.65}(° C.) | 925 | 921 | 885 | 902 | 895 | 914 | 903 | 901 | 891 | 935 |
| T₄ − T_{7.65}(° C.) | 264 | 274 | 283 | 270 | 271 | 311 | 286 | 270 | 283 | 279 |
| T₂ − T₄(° C.) | 284 | 323 | 336 | 307 | 323 | 382 | 305 | 297 | 328 | 357 |
| Manufacturability | x | x | x | x | x | x | x | x | x | x |
| Deflection | ∘ | ∘ | ∘ | ∘ | ∘ | ∘ | x | ∘ | ∘ | ∘ |

### Example 1

In Example 1, a glass having the composition shown in Table 1-1 was produced. In Example 1, a base plate having a diameter of 320 mm and a thickness of 6 mm was manufactured using a melt casting method. Next, a plurality of plates was cut out from the center of the base plate, each plate having a diameter of 300 mm and a thickness of 3 mm. Both surfaces of each plate were polished using cerium oxide as a polishing material to obtain glass having a thickness of 0.7 mm.

For the glass of Example 1, the parameter A was calculated using the above-described Equation (1).

For the glass of Example 1, the parameter B was calculated using the above-described Equation (2).

For the glass of Example 1, the density ρ (g/cm³) was measured. The density was measured by the Archimedes method.

Young's modulus E (GPa) was measured for the glass of Example 1. The Young's modulus was measured by an ultrasonic pulse method defined in JIS R 1602:1995 “Testing methods for elastic modulus of fine ceramics”. The bulk density of a sample was measured by the Archimedes method, and the longitudinal wave velocity and the transverse wave velocity were measured using an ultrasonic thickness meter 38DL PLUS manufactured by Olympus Corporation to determine a value of the Young's modulus.

The linear thermal expansion coefficient α (ppm/° C.) of the glass of Example 1 was measured. The measurement was performed within a range of 0° C. to 350° C. using a thermal expansion meter (DIL 402 Expedis Supreme) manufactured by NETZSCH Group as a measuring apparatus, and an average thermal expansion coefficient within a range of 20° C. to 300° C. in that measurement range was used as the linear thermal expansion coefficient α.

For the glass of Example 1, the melting temperature T₂ (° C.), the working temperature T₃ (° C.), and the molding temperature T₄ (° C.) were measured as high temperature viscosity values. The melting temperature T₂, the working temperature T₃, and the molding temperature T₄ were measured by an inner cylinder rotation method.

The softening temperature T_{7.65} (C) of the glass of Example 1 was measured. The softening temperature T_{7.65} (° C.) was measured by a method defined according to JIS R 3103-1 “Viscosity and viscometric fixed points of glass-Part 1: Determination of softening point”.

The measurement results and the calculation results are shown in Table 1-1.

### Examples 2 to 60

In Examples 2 to 60, glasses were produced in the same manner as in Example 1 except that the composition of each glass was changed as shown in Table 1-1 to Table 1-3. The measurement results and calculation results of each example are shown in Table 1-1 to Table 1-3.

### Evaluation

For the glass of each example, determination of manufacturability and deflection evaluation were performed.

In the determination of manufacturability, a case where the difference (T₂-T₄) was 280° C. or higher and 340° C. or lower and the difference (T₄-T_{7.65}) was 290° C. or higher was evaluated as pass O, and a case where at least one of the difference (T₂-T₄) was 280° C. or higher and 340° C. or lower and the difference (T₄-T_{7.65}) was 290° C. or higher was not satisfied was evaluated as fail ×.

In the deflection evaluation, a glass having a Young's modulus of 80 GPa or more was evaluated as pass ◯, and a glass having a Young's modulus of less than 80 GPa was evaluated as fail ×.

As shown in Table 1, the glass of each of Examples 1 to 41 (Examples) in which the parameter A is 0.817 or less, the parameter B is 0.898 or more, and the ratio (MgO/RO) is 0.65 or more has passed the manufacturability evaluation and the deflection evaluation, and it can be seen that the glasses can be easily manufactured while minimizing the deflection.

On the other hand, in the glass of each of Examples 42 to 60 (Comparative Examples) that does not satisfy at least one of the parameter A of 0.817 or less, the parameter B of 0.898 or more, and the ratio (MgO/RO) of 0.65 or more, at least one of the manufacturability evaluation or the deflection evaluation fails, and it can be seen that manufacturing cannot be easily performed while minimizing deflection.

According to the present invention, it is possible to facilitate the manufacturing while minimizing deflection.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A glass, wherein
a parameter A represented by Equation (1) is 0.817 or less,
a parameter B represented by Equation (2) is 0.898 or more,
a ratio of a content of MgO to a total content of a divalent metal oxide RO is 0.65 or more in terms of mol % on an oxide basis,
a Young's modulus is 80 GPa or more, and
the glass is an alkali-free glass,
$$A = 1.747 - 0.022 \times [ {SiO}_{2} ] + 0.006 \times [ {Al}_{2} {O}_{3} ] + 0.018 \times [ {B}_{2} {O}_{3} ] + 0.013 \times [ MgO ] - 0.01 \times [ CaO ] - 0.003 \times [ SrO ] + 0.012 \times [ BaO ] + 0.015 \times [ ZnO ] , \qquad ( 1 )$$
$$B = 1.315 - 0.01 \times [ {SiO}_{2} ] + 0.005 \times [ {Al}_{2} {O}_{3} ] + 0.023 \times [ {B}_{2} {O}_{3} ] + 0.004 \times [ MgO ] - 0.016 \times [ CaO ] - 0.007 \times [ SrO ] + 0.011 \times [ BaO ] + 0.01 \times [ ZnO ] . \qquad ( 2 )$$

2. The glass according to claim 1, wherein the glass contains, in terms of mol % on an oxide basis,
SiO₂: 55.0% to 65.0%,
Al₂O₃: 3.0% to 13.0%,
B₂O₃: 1.0% to 10.0%, and
RO: 10.0% to 40.0%.

3. The glass according to claim 1, wherein the glass contains, in terms of mol % on an oxide basis,
MgO: 10.0% to 25.0%.

4. The glass according to claim 1, wherein
the glass contains, in terms of mol % on an oxide basis,
CaO: 1.0% to 10.0%.

5. The glass according to claim 1, wherein
the glass contains, in terms of mol % on an oxide basis,
SrO: 0% to 5.0%.

6. The glass according to claim 1, wherein
the glass contains, in terms of mol % on an oxide basis,
BaO: 0% to 5.0%.

7. The glass according to claim 1, wherein
the parameter A is 0.781 or more and 0.817 or less,
the parameter B is 0.903 or more and 0.935 or less, and
the ratio of the content of MgO to the total content of the divalent oxide RO is 0.65 or more and 0.9 or less in terms of mol % on an oxide basis.

8. The glass according to claim 1, wherein
the glass contains, in terms of mol % on an oxide basis,
SiO₂: 61.0% to 63.5%, and
Al₂O₃: 7.0% to 8.5%.

9. The glass according to claim 1, wherein
the glass contains, in terms of mol % on an oxide basis,
MgO: 12% to 22%,
CaO: 1.1% to 7%,
SrO: 0.1% to 5.0%, and
BaO: 0.1% to 5.0%.

10. The glass according to claim 1, wherein the glass does not substantially contain an alkali metal oxide.

11. The glass according to claim 1, wherein a Young's modulus parameter Y represented by Equation (3) is 0.9 or more,
$$Y = ( 60 - 0.244 [ {SiO}_{2} ] + 0.27 [ {Al}_{2} {O}_{3} ] - 0.6 [ {B}_{2} {O}_{3} ] + 0.63 [ MgO ] + 0.48 [ CaO ] - 0.56 [ SrO ] - 0.22 [ BaO ] + 1.37 [ ZnO ] ) / 85. \qquad ( 3 )$$

12. The glass according to claim 1, wherein a ratio (E/ρ) of a Young's modulus E to a density p is 30 GPa·cm³/g or more and 40 GPa·cm³/g or less.

13. The glass according to claim 1, wherein a difference (T₂-T₄) between a melting temperature T₂ and a molding temperature T₄ is 400° C. or lower.

14. The glass according to claim 1, wherein a difference (T₄-T_{7.65}) between a molding temperature T₄ and a softening temperature T_{7.65} is 250° C. or higher.

15. The glass according to claim 1, wherein a ratio of a content of RO to a total content of SiO₂, Al₂O₃, and B₂O₃ ((RO)/(SiO₂+Al₂O₃+B₂O₃)) is 0.2 or more and 0.5 or less.

16. The glass according to claim 1, wherein a total amount (SiO₂+Al₂O₃+MgO+CaO) of SiO₂, Al₂O₃, MgO, and CaO is 85% or more and 98% or less in terms of mol % on an oxide basis.

17. The glass according to claim 1, wherein a difference (Al₂O₃—RO) that is a value obtained by subtracting a content of RO from a content of Al₂O₃ is-30% or more and 0% or less in terms of mol % on an oxide basis.

18. The glass according to claim 1, wherein the glass is used as a substrate.

19. The glass according to claim 15, wherein the glass is used for manufacturing at least one of a fan out wafer level package or a fan out panel level package.
